(19) United States
(12) Patent Application Publication
(10) Pub. No.: US 2016/0197130 A1
(43) Pub. Date: Jul. 7, 2016

(54) DISPLAY DEVICE

(71) Applicant: SAMSUNG DISPLAY CO., LTD., Yongin-si (KR)

(72) Inventors: Elly Gil, Yongin-si (KR); Deok-Hoi Kim, Yongin-si (KR); Jae-Hyun Lee, Yongin-si (KR)

(21) Appl. No.: 14/866,288

(22) Filed: Sep. 25, 2015

(30) Foreign Application Priority Data
Jan. 5, 2015 (KR) 10-2015-0000853

(51) Int. Cl. H01L 27/32; H01L 51/52

(52) U.S. Cl. CPC H01L 27/3265; H01L 27/3276; H01L 51/5253

(57) ABSTRACT

A display device including: a first conductive pattern group including: a scan line and a gate electrode spaced from the scan line, a driving semiconductor pattern below the first conductive pattern group and including: a channel region overlapping the gate electrode; a source region; and a drain region, the channel region between the source region and the drain region; a second conductive pattern group on the first conductive pattern group and including: a data line crossing the scan line; a drain electrode coupled to the drain region; a pixel electrode extending from the drain electrode; a first coupling pattern coupled to the gate electrode; and a driving voltage line coupled to the source region; and a capacitor coupled to the first coupling pattern and the driving voltage line and overlapping the pixel electrode.

### CROSS-REFERENCE TO RELATED APPLICATION

This application claims priority to and the benefit of Korean Patent Application No. 10-2015-0000853, filed on Jan. 5, 2015 in the Korean Intellectual Property Office, the content of which is incorporated herein by reference in its entirety.

### BACKGROUND

1. Field

Embodiments of the present invention relate to a display device.

2. Description of the Related Art

Among display devices, flat panel display devices are popular because they are relatively lightweight and thin films can be used to manufacture them. Among the flat display devices, organic light emitting display devices may be self-radiating display devices that display images using organic light emitting diodes (OLEDs) that emit light without requiring any additional source of light required. In addition, organic light emitting display devices are regarded as the next generation display device because they consume less power than other types of display device and have relatively high brightness and fast response speed.

Organic light emitting display devices may include a plurality of transistors for driving the organic light emitting diodes and a plurality of pixels each including at least one capacitor.

Charging capacity of a capacitor is generally proportional to an overlapping area of electrodes that make up the capacitor. However, there is a limit to how large an area the capacitor may occupy in order to implement high-resolution organic light emitting display devices.

### SUMMARY

Embodiments of the present invention may be realized by providing a display device including: a first conductive pattern group including a scan line and a gate electrode spaced from the scan line; a driving semiconductor pattern below the first conductive pattern group and comprising: a channel region overlapping the gate electrode; a source region; and a drain region, the channel region between the source region and the drain region; a second conductive pattern group on the first conductive pattern group and including: a data line crossing the scan line; a drain electrode coupled to the drain region; a pixel electrode extending from the drain electrode; a first coupling pattern coupled to the gate electrode; and a driving voltage line coupled to the source region; and a capacitor coupled to the first coupling pattern and the driving voltage line and overlapping the pixel electrode.

The capacitor may include: a first capacitor electrode spaced from the driving semiconductor pattern below the first conductive pattern group and overlapping the pixel electrode, a first gate insulating layer on the driving semiconductor pattern and the first capacitor electrode below the first conductive pattern group; a second gate insulating layer on the first gate insulating layer and the first conductive pattern group below the second conductive pattern group; and a second capacitor electrode on the first capacitor electrode with the first and second gate insulating layers therebetween.

The display device may further include: a protruding portion extending from the first capacitor electrode and overlapping the driving voltage line, a protective layer on the second capacitor electrode and below the second conductive pattern group; and a contact portion extending from the driving voltage line towards the protruding portion and passing through the protective layer and the first and second gate insulating layers, the contact portion contacting the protruding portion.

The display device may further include: a protective layer on the second capacitor electrode and below the second conductive pattern group; and a contact portion extending from the first coupling pattern towards the second capacitor electrode and passing through the protective layer, the contact portion contacting the second capacitor electrode.

The first capacitor electrode may include a semiconductor pattern.

The first capacitor electrode may include impurities of a same type as that of the source region and the drain region.

The second capacitor electrode may include a metal layer.

The capacitor may include: a first capacitor electrode spaced from the driving semiconductor pattern below the first conductive pattern group and overlapping the pixel electrode; a first gate insulating layer on the driving semiconductor pattern and the first capacitor electrode below the first conductive pattern group; and a second capacitor electrode on the first capacitor electrode with the first gate insulating layer therebetween and spaced from the scan line and the gate electrode. The first conductive pattern group may further include the second capacitor electrode

The display device may further include: a protruding portion extending from the first capacitor electrode and overlapping the driving voltage line; a second gate insulating layer on the first conductive pattern group and below the second conductive pattern group; a protective layer on the second gate insulating layer below the second conductive pattern group; and a contact portion extending from the driving voltage line towards the protruding portion and passing through the protective layer and the first and second gate insulating layers, the contact portion contacting the protruding portion.

The display device may further include: a second gate insulating layer on the first conductive pattern group and below the second conductive pattern group; a protective layer on the second gate insulating layer below the second conductive pattern group; and a contact portion extending from the first coupling pattern towards the second capacitor electrode and passing through the protective layer and the second gate insulating layer, the contact portion contacting the second capacitor electrode.

The first capacitor electrode may include a semiconductor pattern.

The first capacitor electrode may include an undoped area overlapping the second capacitor electrode and a doped area offset from the second capacitor electrode.

The doped area may include impurities of a same type as that of the source region and the drain region.

The capacitor may include: a first capacitor electrode overlapping the pixel electrode on a first gate insulating layer, on the driving semiconductor pattern, and spaced from the scan line and the gate electrode; a second gate insulating layer on the first conductive pattern group and on the first gate insulating layer; and a second capacitor electrode on the first capacitor electrode with the second gate insulating layer therebetween and below the second conductive pattern group. The first conductive pattern group may further include the first capacitor electrode.

The display device may further include: a protective layer on the second capacitor electrode below the second conductive pattern group and on the second gate insulating layer; and a contact portion extending from the first coupling pattern towards the first capacitor electrode and passing through the protective layer and the second gate insulating layer, the contact portion contacting the first capacitor electrode.

The display device may further include: a protruding portion extending from the second capacitor electrode and overlapping the driving voltage line; a protective layer on the second capacitor electrode, on the protruding portion on the second gate insulating layer, and below the second conductive pattern group; and a contact portion extending from the driving voltage line towards the protruding portion and passing through the protective layer, the contact portion contacting the protruding portion.

The second capacitor electrode may include a metal layer.

The capacitor may include: a first capacitor lower electrode overlapping the pixel electrode and spaced from the driving semiconductor pattern; a first gate insulating layer on the driving semiconductor pattern and the first capacitor lower electrode; a second capacitor electrode overlapping the first capacitor lower electrode on the first gate insulating layer and spaced from the scan line and the gate electrode; a second gate insulating layer on the first conductive pattern group and on the first gate insulating layer; and a first capacitor upper electrode coupled to the first capacitor lower electrode and overlapping the second capacitor electrode. The first conductive pattern group may further include the second capacitor electrode.

The first capacitor lower electrode may include: an undoped area overlapping the second capacitor electrode and a doped area offset from the second capacitor electrode and including impurities of a same type as that of the source region and the drain region.

The display device may further include: a protective layer on the first capacitor upper electrode below the second conductive pattern group and on the second gate insulating layer; a protruding portion extending from the first capacitor upper electrode to overlap the driving voltage line; a first contact portion extending from the driving voltage line towards the protruding portion and passing through the protective layer, the first contact portion contacting the protruding portion; a second contact portion extending from the first coupling pattern towards the second capacitor electrode and passing through the protective layer and the second gate insulating layer, the second contact portion contacting the second capacitor electrode; a second coupling pattern on the protective layer and overlapping the first capacitor lower electrode and the first capacitor upper electrode; a third contact portion extending from the second coupling pattern towards the first capacitor lower electrode and passing through the protective layer and the first and second gate insulating layers, the third contact portion contacting the first capacitor lower electrode; and a fourth contact portion extending from the second coupling pattern towards the first capacitor upper electrode and passing through the protective layer, the fourth contact portion contacting the first capacitor upper electrode. The second conductive pattern group may further include the second coupling pattern.

### BRIEF DESCRIPTION OF THE DRAWINGS

Example embodiments of the present invention will now be described more fully hereinafter with reference to the accompanying drawings; however, the present invention may be embodied in different forms and should not be construed as limited to the embodiments set forth herein. Rather, these embodiments are provided so that this disclosure will be thorough and complete and will fully convey the scope of the present invention to those skilled in the art.

In the figures, dimensions may be exaggerated for clarity of illustration.

FIG. 1 is a circuit diagram illustrating a display device according to an embodiment of the present invention.

FIG. 2 is a plane view illustrating a pixel according to an embodiment of the present invention.

FIGS. 3A and 3B are sectional diagrams illustrating a display device taken along the lines shown in FIG. 2.

FIG. 4 is a plane view illustrating a pixel according to an embodiment of the present invention.

FIG. 5 is a cross-sectional view illustrating a display device taken along the lines shown in FIG. 4.

FIG. 6 is a plane view illustrating a pixel according to an embodiment of the present invention.

FIG. 7 is a cross-sectional view illustrating a display device taken along the lines shown in FIG. 6.

FIG. 8 is a plane view illustrating a pixel according to an embodiment of the present invention.

FIGS. 9A and 9B are cross-sectional views illustrating a display device taken along the lines shown in FIG. 8.

FIGS. 10A and 10B are diagrams of a mask process for manufacturing a display device according to an embodiment of the present invention.

### DETAILED DESCRIPTION

In the following detailed description, only certain exemplary embodiments of the present invention are shown and described, simply by way of illustration. As those skilled in the art would realize, the described embodiments may be modified in various different ways, all without departing from the spirit or scope of the present invention. Accordingly, the drawings and description are to be regarded as illustrative in nature and not restrictive. In addition, it will be understood that when an element or layer is referred to as being “on”, “connected to,” or “coupled to” another element or layer, it can be directly on, connected, or coupled to the other element or layer or intervening elements or layers may be present. When an element is referred to as being “directly on,” “directly connected to,” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers, and/or sections, these elements, components, regions, layers, and/or sections should not be limited by these terms. These terms are only used to distinguish one element, component, region, layer, or section from another region, layer, or section. Thus, a first element, component, region, layer, or section discussed below could be termed a second element, component, region, layer, or section without departing from the teachings of the present invention.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms, “a” and “an” are intended to include the plural forms as well, unless the context clearly indicates otherwise. It will be further understood that the terms “comprises,” “comprising,” “includes,” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. As used herein, the terms “use,” “using,” and “used” may be considered synonymous with the terms “utilize,” “utilizing,” and “utilized,” respectively. Also, the term “exemplary” is intended to refer to an example or illustration. Expressions, such as “at least one of,” when preceding a list of elements, modify the entire list of elements and do not modify the individual elements of the list. Further, the use of “may” when describing embodiments of the present invention relates to “one or more embodiments of the present invention”.

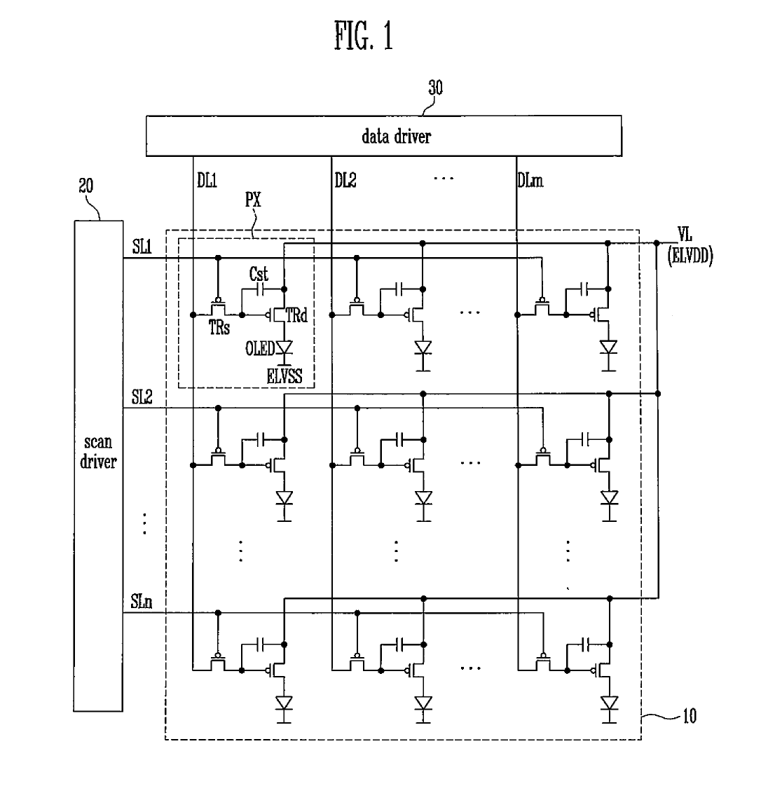

FIG. 1 is a circuit diagram illustrating a display device according to an embodiment of the present invention.

Referring to FIG. 1, a display device according to an embodiment may include a display portion 10 for displaying images, a scan driver 20, and a data driver 30.

The display portion 10 may include pixels PX arranged in a matrix form, scan lines SL1 to SLn, data lines DL1 to DLm, and a driving voltage line VL.

Each of the pixels PX may include a switching transistor TRs, a driving transistor TRd, a capacitor Cst, and an organic light emitting diode OLED. Each of the pixels PX may further include a plurality of transistors in addition to the switching transistor TRs and the driving transistor TRd.

The driving transistor TRd may include a control terminal coupled to the switching transistor TRs, an input terminal coupled to the driving voltage line VL, and an output terminal coupled to the organic light emitting diode OLED.

The switching transistor TRs may include a control terminal coupled to one of the scan lines SL1 to SLn, an input terminal coupled to one of the data lines DL1 to DLm, and an output terminal coupled to the driving transistor TRd.

The capacitor Cst may be coupled between the control terminal of the driving transistor TRd and the driving voltage line VL. The capacitor Cst may charge a voltage according to a data signal applied to the control terminal of the driving transistor TRd and maintain the voltage (e.g., the charged voltage) that is charged even after the switching transistor TRs is turned off.

The organic light emitting diode OLED may include an electrode coupled to the output terminal of the driving transistor TRs and an electrode coupled to a common voltage ELVSS.

If a plurality of transistors is added to the pixel PX, in addition to the driving transistor TRd and the switching transistor TRs, a coupling relationship and the like between the driving transistor TRd and the switching transistor TRs may change.

That is, the pixel structure shown in FIG. 1 is just one example; the pixel PX is not limited to the pixel structure.

The pixel PX may have any one of various structures described thus far or any other suitable structure known to those skilled in the art.

The scan lines SL1 to SLn may transfer scan signals. The scan lines SL1 to SLn may extend parallel to each other along a first direction.

The data lines DL1 to DLm may transfer data signals. The data lines DL1 to DLm may extend parallel to each other along a second direction crossing the first direction.

The scan lines SL1 to SLn and the data lines DL1 to DLm crossing each other may form a plurality of divided sections having a matrix form. Each of the divided sections outlined (e.g., surrounded) by the scan lines SL1 to SLn and the data lines DL1 to DLm crossing each other may be divided into a transistor region and an emission region.

The driving voltage line VL may transfer power voltage ELVDD and may be formed in a mesh form. A portion of the driving voltage line VL may be parallel to the data lines DL1 to DLm.

The scan driver 20 may be coupled to the display portion 10 via the scan lines SL1 to SLn. Scan signals from the scan driver 20 may be supplied to the pixels PX via the scan lines SL1 to SLn.

The data driver 30 may be coupled to the display portion 10 via the data lines DL1 to DLm. Data signals may be supplied to the pixels PX from the data driver 30 via the data lines DL1 to DLm.

Each of the pixels PX that receives the above-described scan signal and data signal may control ON/OFF of the driving transistor TRd through the switching transistor TRs. The driving transistor TRd may supply driving current to the organic light emitting diode OLED according to the data signals. The organic light emitting diode OLED that receives the driving current may generate light corresponding to (e.g., according to or based on) the driving current.

Hereinafter, structure of the capacitor Cst according to embodiments of the present invention will be described in detail with reference to any one of the pixels PX.

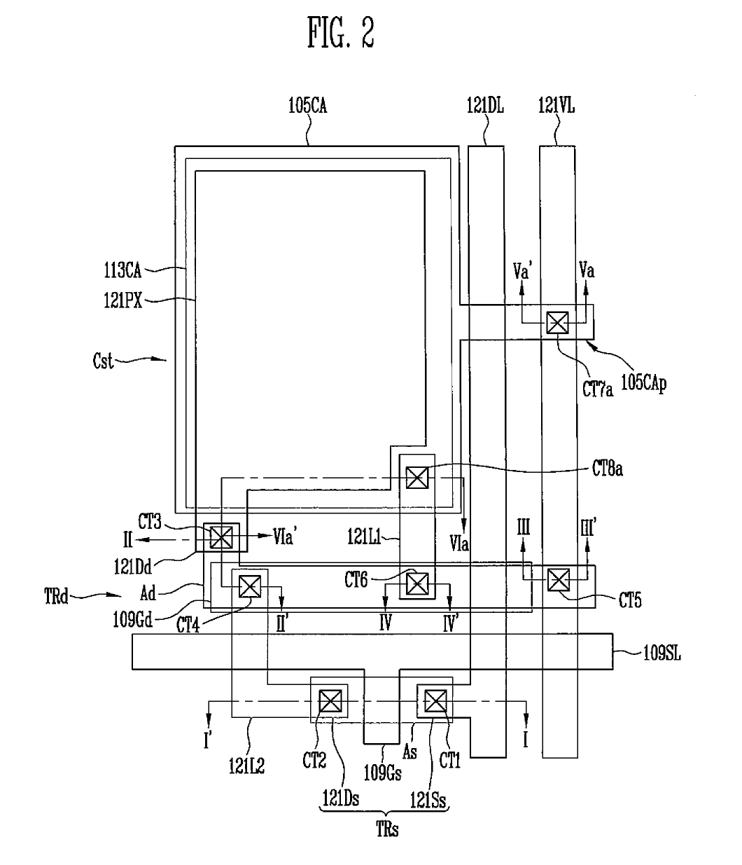

FIG. 2 is a plane view illustrating a pixel according to an embodiment of the present invention.

Referring to FIG. 2, a pixel may be electrically coupled to a scan line 109SL, a data line 121DL, and a driving voltage line 121VL via a switching transistor TRs and a driving transistor TRd. The pixel may include a capacitor Cst coupled to the driving transistor TRd. The switching transistor TRs and the driving transistor TRd may be electrically coupled to each other via a second coupling pattern 121L2.

The scan line 109SL and the data line 121DI may cross each other. A region that is sectioned off by the scan line 109SL and the data line 121DL crossing each other may be divided into a transistor region and an emission region. In the transistor region, a plurality of transistors including the switching transistor TRs and the driving transistor TRd may be disposed. In the emission region, the organic light emitting diode OLED including a pixel electrode 121PX may be disposed. The emission region may occupy a larger area than the transistor region. The driving voltage line 121VL may extend in parallel to the data line 121DL and be next to the data line 121DL. The data line 121DL may be disposed between the pixel electrode 121PX and the driving voltage line 121VL.

The switching transistor TRs may include a switching gate electrode 109Gs, a switching source electrode 121Ss, a switching drain electrode 121Ds, and a switching semiconductor pattern As. The switching gate electrode 109Gs may protrude from the scan line 109SL. The switching source electrode 121Ss may protrude from the data line 121DL. The switching drain electrode 121Ds may face the switching source electrode 121Ss with the switching gate electrode 109Gs therebetween. The switching semiconductor pattern As may extend to overlap the switching gate electrode 109Gs, the switching drain electrode 121Ds, and the switching source electrode 121Ss. The switching source electrode 121Ss may be coupled to the switching semiconductor pattern As via a first contact portion CT1, and the switching drain electrode 121Ds may be coupled to the switching semiconductor pattern As via a second contact portion CT2.

The second coupling pattern 121L2 may extend from the switching drain electrode 121Ds towards a region where the driving transistor TRd is disposed.

The driving transistor TRd may include a driving gate electrode 109Gd, a driving drain electrode 121Dd, a portion of the driving voltage line 121VL used as (e.g., acting as) a driving source electrode, and a driving semiconductor pattern Ad. The driving gate electrode 109Gd may be spaced from (e.g., spaced apart from) the scan line 109SL. The second coupling pattern 121L2 may extend from the switching drain electrode 121Ds to overlap at least a portion of the driving gate electrode 109Gd. The driving drain electrode 121Dd may protrude from the pixel electrode 121PX formed in the emission region. The driving drain electrode 121Dd may face the portion of the driving voltage line 121VL used as the driving source electrode with the driving gate electrode 109Gd therebetween. The driving semiconductor pattern Ad may extend to overlap the driving gate electrode 109Gd, the driving drain electrode 121Dd, and the portion of the driving voltage line 121VL used as the driving source electrode. The driving drain electrode 121Dd may be coupled to the driving semiconductor pattern Ad via a third contact portion CT3. The driving gate electrode 109Gd may be coupled to the second coupling pattern 121L2 via a fourth contact portion CT4. The driving voltage line 121VL used as the driving source electrode may be coupled to the driving semiconductor pattern Ad via a fifth contact portion CT5.

The first coupling pattern 121L1 may be formed to overlap at least a portion of the driving gate electrode 109Gd. The first coupling pattern 121L1 may be coupled to the driving gate electrode 109Gd via a sixth contact portion CT6 formed at an overlapping portion of the first coupling pattern 121L1 and the driving gate electrode 109Gd. The first coupling pattern 121L1 may extend towards a region where the capacitor Cst is formed to overlap at least a portion of the capacitor Cst.

The capacitor Cst may be disposed to overlap the pixel electrode 121PX extending from the driving drain electrode 121Dd to the emission region. The pixel electrode 121PX may be used as an anode electrode or a cathode electrode of the organic light emitting diode. The pixel electrode 121PX may be formed in the emission region that occupies relatively a large area. Therefore, when the capacitor Cst is disposed in the emission region and overlaps the pixel electrode 121PX, charge capacity of the capacitor Cst may increase more than if the capacitor Cst was disposed in the transistor region and overlapped the driving transistor TRd.

The capacitor Cst may include a first capacitor electrode 105CA overlapping the pixel electrode 121PX and a second capacitor electrode 113CA overlapping the pixel electrode 121PX.

The first capacitor electrode 105CA may be coupled to the driving voltage line 121VL via a protruding portion 105CAp and a seventh contact portion CT7a. The protruding portion 105CAp may extend from the first capacitor electrode 105CA and overlap at least a portion of the driving voltage line 121VL. The seventh contact portion CT7a may be disposed at an overlapping portion of the protruding portion 105CAp and the driving voltage line 121VL.

The second capacitor electrode 113CA may be coupled to the driving transistor TRd via the first coupling pattern 121L1 and an eighth contact portion CT8a. The first coupling pattern 121L1 may extend to overlap the second capacitor electrode 113CA. The eighth contact portion CT8a may be disposed at an overlapping portion of the first coupling pattern 121L1 and the second capacitor electrode 113CA.

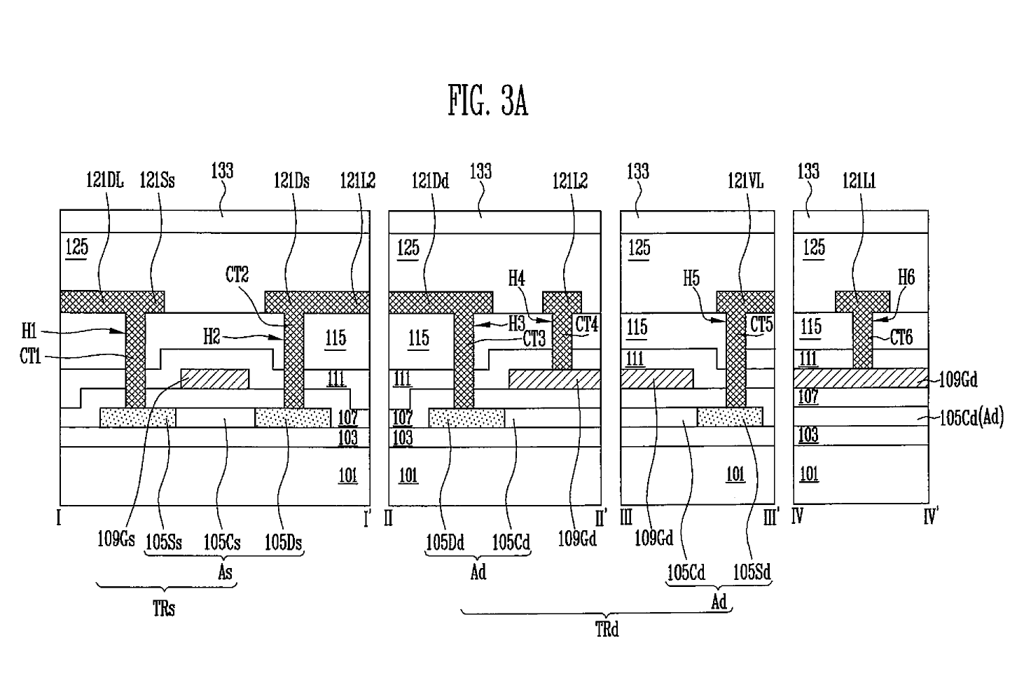

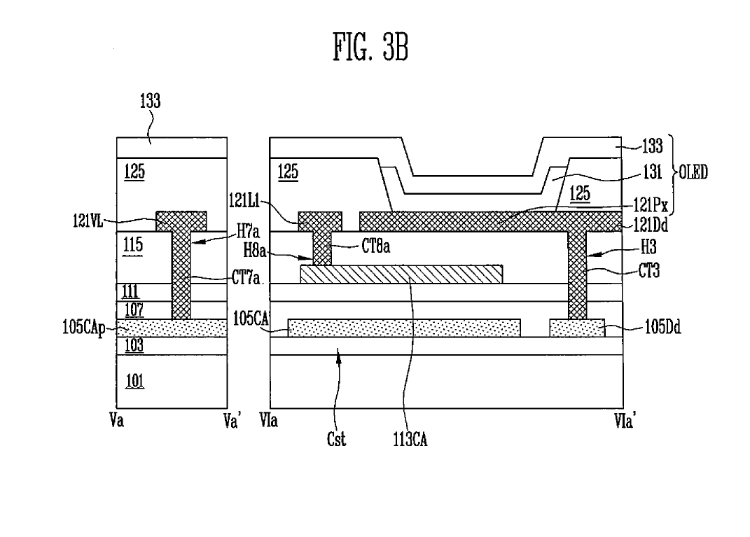

FIGS. 3A and 3B are cross-sectional views illustrating the display device shown in FIG. 2 taken along the lines “I-I′”, “II-II′”, “III-III′”, “IV-IV′”, “Va-Va′”, and “Vla-Vla′”, of FIG. 2 as indicated.

Referring to FIGS. 3A and 3B, a buffer layer 103 may be formed on a substrate 101, and a switching transistor TRs, a driving transistor TRd, and a capacitor Cst may be formed on the buffer layer 103.

The substrate 101 may be formed of a glass or a transparent plastic material through which light transmission or light penetration is possible. The buffer layer 103 may include silicon oxide layer and/or silicon nitride layer. The buffer layer 103 may prevent impurities from spreading and moisture or oxygen from penetrating. The buffer layer 103 may flatten a surface (e.g., planarize a surface) of the substrate 101.

Semiconductor pattern groups As, Ad, 105CA, and 105CAp may be formed on the substrate 101 with the buffer layer 103 therebetween. The semiconductor pattern groups As, Ad, 105CA, and 105CAp may include a switching semiconductor pattern As, a driving semiconductor pattern Ad, a first capacitor electrode 105CA, and a protruding portion 105CAp. The semiconductor pattern groups As, Ad, 105CA, and 105CAp may be formed by patterning a semiconductor layer using a mask process. The semiconductor layer may include polycrystalline silicon or oxide semiconductor. The oxide semiconductor may include Zn, In, GA, Sn, or a mixture thereof. For example, but without limitation thereto, the oxide semiconductor may include indium-gallium-zinc oxide (IGZO).

The switching semiconductor pattern As may include an impurities-doped source region 105Ss, an impurities-doped drain region 105Ds, and a channel region 105Cs disposed between the source region 105Ss and the drain region 105Ds. The same impurities may be doped in the source region 105Ss and the drain region 105Ds. The channel region 105Cs may be a region that overlaps a switching gate electrode 109Gs. The source region 105Ss and the drain region 105Ds may be regions that do not overlap the switching gate electrode 109Gs.

The driving semiconductor pattern Ad may include an impurities-doped source region 105Sd, an impurities-doped drain region 105Dd, and a channel region 105Cd disposed between the source region 105Sd and the drain region 105Dd. The same impurities may be doped in the source region 105Sd and the drain region 105Dd. The channel region 105Cd may be a region that overlaps a driving gate electrode 109Gd. The source region 105Sd and the drain region 105Dd may be regions that do not overlap the driving gate electrode 109Gd.

The first capacitor electrode 105CA may be spaced from the switching semiconductor pattern As and the driving semiconductor pattern Ad and be disposed to overlap the pixel electrode 121PX. The protruding portion 105CAp may extend from the first capacitor electrode 105CA. The first capacitor electrode 105CA and the protruding portion 105CAp may include the same type of impurities as the source regions 105Ss and 105Sd and the drain regions 105Ds and 105Dd.

A first gate insulating layer 107 may be formed on the buffer layer 103 that covers the semiconductor pattern groups As, Ad, 105CA, and 105CAp. The first gate insulating layer 107 may include silicon oxide and/or silicon nitride.

A first conductive pattern group 109SL, 109Gs, and 109Gd may be formed on the first gate insulating layer 107. The first conductive pattern group 109SL, 109Gs, and 109Gd may include a scan line 109SL, a switching gate electrode 109Gs, and a driving gate electrode 109Gd. The first conductive pattern group 109SL, 109Gs, and 109Gd may be formed by patterning a first conductive layer using one mask process. The first conductive layer may include aluminum, silver, copper, molybdenum, chrome, tantalum, titanium, a combination thereof, or an alloy thereof.

The switching gate electrode 109Gs may protrude from the scan line 109SL as shown in FIG. 2. The switching gate electrode 109Gs may overlap the channel region 105Cs of the switching semiconductor pattern As. The drain region 105Ds and the source region 105Ss of the switching semiconductor pattern As may protrude toward respective sides of the switching gate electrode 109Gs.

The driving gate electrode 109Gd may overlap the channel region 105Cd of the driving semiconductor pattern Ad. The drain region 105Dd and the source region 105Sd of the switching semiconductor pattern Ad may protrude toward respective sides of the driving gate electrode 109Gd.

The first capacitor electrode 105CA and the protruding portion 105CAp may be exposed by the first conductive pattern group 109SL, 109Gs, and 109Gd.

A second gate insulating layer 111 that covers the first conductive pattern group 109SL, 109Gs, and 109Gd may be formed on the first gate insulating layer 107. The second gate insulating layer 111 may include silicon oxide and/or silicon nitride.

The second capacitor electrode 113CA may be formed on the second gate insulating layer 111. The second capacitor electrode 113CA may overlap the first capacitor electrode 105CA with the first and second gate insulating layers 107 and 111 therebetween. The second capacitor electrode 113CA may be disposed at a lower side of the pixel electrode 121 PX. The second capacitor electrode 113CA may be formed by patterning a capacitor conductive layer using one mask process. The capacitor conductive layer may be formed of a metal layer that includes aluminum, silver, copper, molybdenum, chrome, tantalum, titanium, a combination thereof, or an alloy thereof.

A protective layer 115 that covers the second capacitor electrode 113CA may be formed on the second gate insulating layer 111. The protective layer 115 may be formed as a single layer or as a multi-layer structure including two or more layers. The protective layer 115 may include an inorganic layer and an organic layer stacked on the inorganic layer. The inorganic layer may include silicon oxide and/or silicon nitride. The organic layer may include acryl, polyimide, polyamide, and/or benzocyclobutene. An organic protective layer may be transparent and may be flexible. The organic protective layer may be a flattening layer (e.g., a planarization layer) capable of providing a flat or substantially flat surface above a curved lower side structure or layer by easing the curvature of the lower side structure or layer.

A contact opening group (e.g., a contact hole group) including first to eighth contact openings H1 to H8a (e.g., contact holes) may pass through the protective layer 115, the second gate insulating layer 111, and/or the first gate insulating layer 107. The contact opening group may be formed by patterning the protective layer 115, the second gate insulating layer 111, and/or the first gate insulating layer 107 using one mask process.

The first contact opening H1, the second contact opening H2, the third contact opening H3, the fifth contact opening H5 and the seventh contact opening H7a may pass through the protective layer 115, the second gate insulating layer 111, and/or the first gate insulating layer 107. The first contact opening H1 may expose the source region 105Ss of the switching semiconductor pattern As and be disposed at the lower side of the switching source electrode 121Ss. The second contact opening H2 may expose the drain region 105Ds of the switching semiconductor pattern As and be disposed at the lower side of the switching drain electrode 121Ds. The third contact opening H3 may expose the drain region 105Dd of the driving semiconductor pattern Ad and be disposed at the lower side of the driving drain electrode 121Dd. The fifth contact opening H5 may expose the source region 105Sd of the driving semiconductor pattern Ad and be disposed at the lower side of the driving voltage line 121VL. The seventh contact opening H7a may expose the protruding portion 105CAp and be disposed at the lower side of the driving voltage line 121VL.

The fourth contact opening H4 and the sixth contact opening H6 may pass through the protective layer 115 and the second gate insulating layer 111. The fourth contact opening H4 and the sixth contact opening H6 may expose the driving gate electrode 109Gd and be spaced from each other. The fourth contact opening H4 may be disposed at the lower side of the second coupling pattern 121L2. The sixth contact opening H6 may be disposed at the lower side of the first coupling pattern 121L1.

The eighth opening hole H8a may pass through the protective layer 115 and expose the second capacitor electrode 113CA.

A second conductive pattern group CT1 to CT8a, 121DL, 121Ss, 121Ds, 121L1, 121L2, 121Dd, 121VL, and 121PX may be formed in the contact opening group H1 to H8a and on the protective layer 115 (e.g., the various constituent elements of the second conductive pattern group may be in various one or more of the openings of the contact opening group and/or be on the protective layer 115). The second conductive pattern group CT1 to CT8a, 121DL, 121Ss, 121Ds, 121L1, 121L2, 121Dd, 121VL, and 121PX may include first to eighth contact portions CT1 to CT8a that fill the contact opening group H1 to H8a, a data line 121DL, a switching source electrode 121Ss, a switching drain electrode 121Ds, first and second coupling patterns 121L1 and 121L2, a driving drain electrode 121Dd, the driving voltage line 121VL, and the pixel electrode 121PX. The second conductive pattern group CT1 to CT8a, 121DL, 121Ss, 121Ds, 121L1, 121L2, 121Dd, 121VL, and 121PX may fill the contact opening group H1 to H8a and may be formed by patterning the second conductive layer formed on the protective layer 115 using one mask process. The second conductive layer may include aluminum and/or an alloy thereof.

The data line 121DL may cross the scan line 109SL as shown in FIG. 2 and may be disposed on the protective layer 115.

The switching source electrode 121Ss may be disposed on the protective layer 115 by protruding from the data line 121DL as shown in FIG. 2 and may overlap the first contact opening H1. The first contact portion CT1 may extend from the switching source electrode 121Ss and fill an inside of the first contact opening H1. The first contact portion CT1 may contact the source region 109Ss of the switching semiconductor pattern As.

The switching drain electrode 121Ds may be disposed on the protective layer 115 to overlap the second contact opening H2. The second contact portion CT2 may fill an inside of the second contact opening H2 by extending from the switching drain electrode 121Ds. The second contact portion CT2 may contact the drain region 109Ds of the switching semiconductor pattern As.

The first coupling pattern 121L1 may be disposed on the protective layer 115 and extend such that ends thereof overlap the sixth contact opening H6 and the eighth contact opening H8a. The sixth contact portion CT6 may fill an inside of the sixth contact opening H6 by extending from the first coupling pattern 121L1 and may contact the driving gate electrode 109Gd. The eighth contact portion CT8a may fill an inside of the eighth contact opening H8a by extending from the first coupling pattern 121L1 and may contact the second capacitor electrode 113CA.

The second coupling pattern 121L2 may extend from the switching drain electrode 121Ds towards the fourth contact opening H4 on the protective layer 115. The second coupling pattern 121L2 may overlap the fourth contact opening H4. The fourth contact portion CT4 may fill an inside of the fourth contact opening H4 by extending from the second coupling pattern 121L2 and contact the driving gate electrode 109Gd.

The driving drain electrode 121Dd may be disposed on the protective layer 115 to overlap the third contact opening H3. The third contact portion CT3 may fill an inside of the third contact opening H3 by extending from the driving drain electrode 121Dd and contact the drain region 105Dd of the driving semiconductor pattern Ad.

The pixel electrode 121PX may be disposed on the protective layer 115 and extend from the driving drain electrode 121Dd towards the emission region. At a lower side of the pixel electrode 121PX, the first and second capacitor electrodes 105CA and 113CA may overlap the pixel electrode 121PX.

A pixel defining layer 125 that covers the second conductive pattern group CT1 to CT8a, 121DL, 121Ss, 121Ds, 121L1, 121L2, 121Dd, 121VL and 121PX and that includes openings (e.g., open holes) that expose the pixel electrode 121PX may be formed on the protective layer 115.

An organic light emitting layer 131 may be formed on the pixel electrode 121PX exposed by the openings of the pixel defining layer 125. A common electrode 133 may be formed on the organic light emitting layer 131. The organic light emitting diode OLED may include the pixel electrode 121PX, the organic light emitting layer 131, and the common electrode 133. Either the pixel electrode 121PX or the common electrode 133 may be used as an anode electrode, and the other one may be used as a cathode electrode. The organic light emitting layer 131 may be a multi-layer structure that includes an emission layer. For example, but without limitation thereto, the organic light emitting layer 131 may include a hole injection layer that injects holes, a hole transport layer for increasing recombination of holes and electrons by facilitating transport of holes and restricting movement of electrons that could not be combined at the emission layer, an emission layer that expresses light by recombination of electrons and holes that are injected thereto, a hole blocking layer that restricts movement of holes that could not be recombined, an electron transport layer that transports electrons to the emission layer smoothly, and an electron injection layer that injects electrons. The common electrode 133 may be formed of a transparent conductive layer. Light from the organic light emitting layer 131 may be emitted in an upper direction (e.g., in a direction toward the common electrode 133).

According to the above-described structure, the capacitor Cst may include first and second capacitor electrodes 105CA and 113CA respectively on first and second gate insulating layers 111 and 107 and overlapping the pixel electrode 121PX. The capacitor Cst may be disposed in the emission region and, thus, does not occupy additional space on the substrate 101 (e.g., space in the transistor region). Because the first and second capacitor electrodes 105CA and 113CA may be formed as large as the pixel electrode 121 PX, a capacity of the capacitor Cst may be sufficiently ensured.

According to the above-described structure, even when the protruding portion 105Cap protruding from the first capacitor electrode 105CA is formed on a layer different from that on which the driving voltage line 121VL, the protruding portion 105CAp may be electrically coupled to the driving voltage line 121VL via the fifth contact portion CT5. When the first capacitor electrode 105CA and the protruding portion 105CAp may be formed on a layer different from the driving voltage line 121VL and the data line DL is formed on a layer that is the same layer as the driving voltage line 121VL, the data line DL and the protruding portion 105CAp may be insulated from each other even though the data line DL and the protruding portion 105CAp cross each other as shown in FIG. 2. Accordingly, the data line DL may be disposed between the pixel electrode 121PX and the driving voltage line 121VL as shown in FIG. 2.

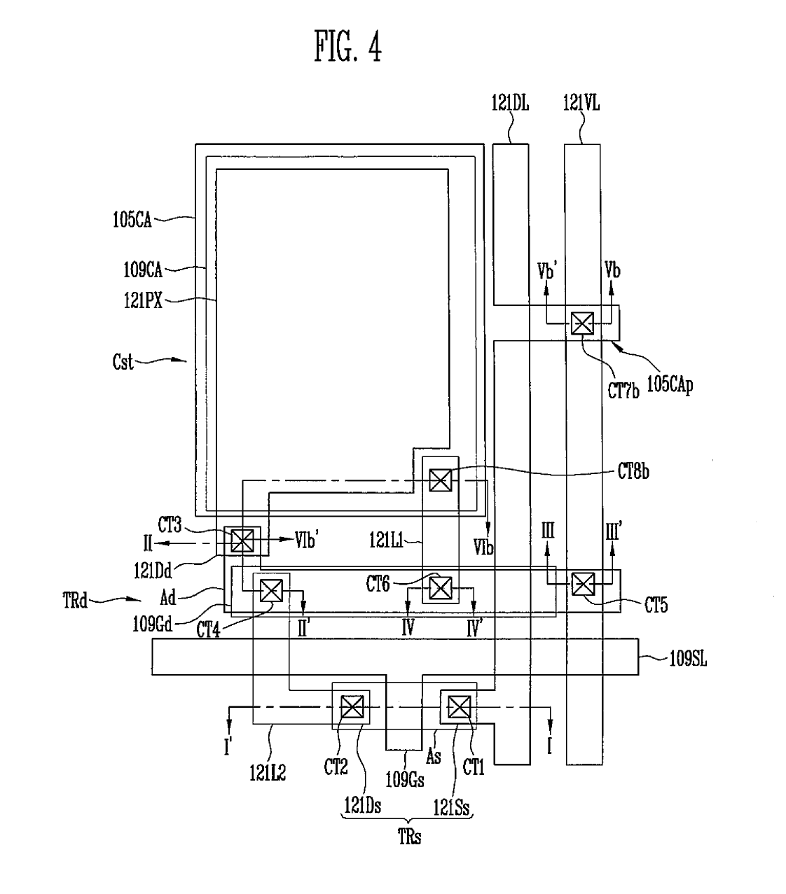

FIG. 4 is a plane view illustrating a pixel according to an embodiment of the present invention.

Referring to FIG. 4, the pixel may be electrically coupled to the scan line 109SL, the data line 121DL, and the driving voltage line 121VL via the switching transistor TRs and the driving transistor TRd. The pixel may include the capacitor Cst that is coupled to the driving transistor TRd via the first coupling pattern 121L1. The switching transistor TRs and the driving transistor TRd may be electrically coupled to each other via the second coupling pattern 121L2.

The scan line 109SL, the data line 121DL, the first and second coupling patterns 121L1 and 121L2, and the driving voltage line 121VI may be formed to have the same or substantially the same layout as described in FIG. 2.

The switching source electrode 121Ss, the switching drain electrode 121Ds, the switching semiconductor pattern As, and the switching gate electrode 109Gs that make up the switching transistor TRs may be formed to have the same or substantially the same layout as shown in FIG. 2. The switching source electrode 121Ss may extend from the data line 121DL and contact the switching semiconductor pattern As via the first contact portion CT1. The switching drain electrode 121Ds may extend from the second coupling pattern 121L2 and contact the switching semiconductor pattern As via the second contact portion CT2.

The driving source electrode (a portion of the driving voltage line 121VL), the driving drain electrode 121Dd, the driving semiconductor pattern Ad, and the driving gate electrode 109Gd that make up the driving transistor TRd may be formed to have the same or substantially the same layout as described in FIG. 2. The driving semiconductor pattern Ad may extend to overlap the driving drain electrode 121Dd and contact the driving drain electrode 121Dd via the third contact portion CT3. The driving semiconductor pattern Ad may extend towards the driving voltage line 121VL and contact the driving voltage line 121VL via the fifth contact portion CT5. The driving gate electrode 109Gd may be coupled to the second coupling pattern 121L1 that is extended to overlap the driving gate electrode 109Gd via the sixth contact portion CT6.

The capacitor Cst may be disposed to overlap the pixel electrode 121PX extending from the driving drain electrode 121Dd to the emission region. The pixel electrode 121PX may be formed to have the same or substantially the same layout as described in FIG. 2. The capacitor Cst may have a relatively large capacity as described with respect to FIG. 2 because the capacitor Cst overlaps the pixel electrode 121PX.

The capacitor Cst may include the first capacitor electrode 105CA and the second capacitor electrode 109CA overlapping the pixel electrode 121PX.

The first capacitor electrode 105CA may be coupled to the driving voltage line 121VL via the protruding portion 105CAp and the seventh contact portion CT7b. The protruding portion 105CAp may extend from the first capacitor electrode 105CA and overlap at least a portion of the driving voltage line 121VL. The seventh contact portion CT7b may overlap an overlapping portion of the protruding portion 105CAp and the driving voltage line 121VL.

The second capacitor electrode 109CA ma be coupled to the driving transistor TRd via the first coupling pattern 121L1 and the eighth contact portion CT8b. The first coupling pattern 121L1 may extend to overlap the second capacitor electrode 109CA. The eighth contact portion CT8b may be disposed at an overlapping portion of the first coupling pattern 121L1 and the second capacitor electrode 109CA.

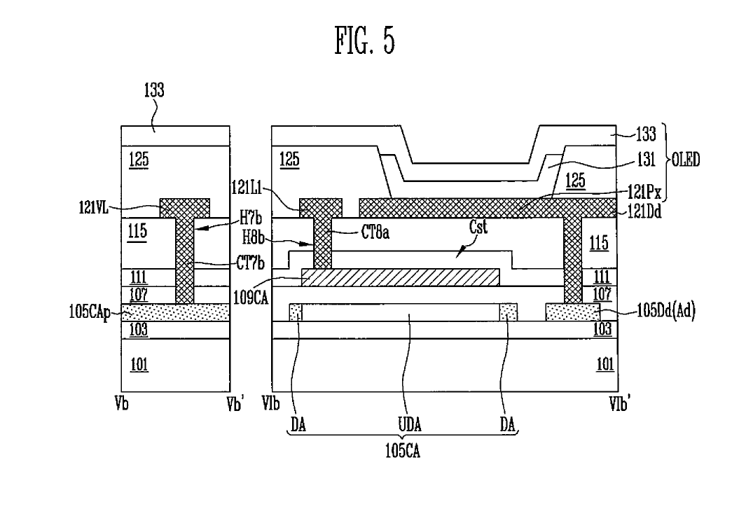

FIG. 5 is a cross-sectional view illustrating the display device as shown in FIG. 4 taken along the lines “Vb-Vb′” and “VIb-VIb′”. Cross sections of the display device along the lines “I-I′”, “II-II′”, “III-III′” and “IV-IV′” of FIG. 4 are the same or substantially the same as shown in FIG. 4.

Referring to FIGS. 3A and 5, a buffer layer 13 may be formed on a substrate 101. A switching transistor TRs, a driving transistor TRd, and a capacitor Cst may be formed on the buffer layer 103.

A semiconductor pattern group As, Ad, 105CA, and 105CAp may be formed on the substrate 101 with the buffer layer 103 therebetween. The semiconductor pattern group As, Ad, 105CA, and 105CAp may include a switching semiconductor pattern As, a driving semiconductor pattern Ad, a first capacitor electrode 105CA, and a protruding portion 105CAp. The semiconductor pattern group As, Ad, 105CA, and 105CAp may be formed by patterning a semiconductor layer using one mask process.

The switching semiconductor pattern As and the structure and the components of the driving semiconductor pattern Ad may be the same or substantially the same as that described in FIGS. 3A and 3B. The structure and the components of the first capacitor electrode 105CA and the protruding portion 105CAp may be the same or substantially the same as that described in FIGS. 3A and 3B. The first capacitor electrode 105CA may include an un-doped area UDA and a doped area DA. The un-doped area UDA may be a region that overlaps a second capacitor electrode 109CA. A doped area DA of the first capacitor electrode 105CA and a doped area DA of the protruding portion 105CAp may be regions that do not overlap the second capacitor electrode 109CA. The doped area DA of the first capacitor electrode 105CA and the doped area of the protruding portion 105CAp may include impurities having a same type as that of source regions 105Ss and 105Sd and drain regions 105Ds and 105Dd.

A first gate insulating layer 107 that covers the semiconductor pattern group As, Ad, 105CA, and 105CAp may be formed on the buffer layer 103.

A first conductive pattern group 109SL, 109GS, 109Gd, and 109CA illustrated in FIG. 4 may be formed on the first gate insulating layer 107. The first conductive pattern group 109SL, 109Gs, 109Gd, and 109CA may include a scan line 109SL, a switching gate electrode 109Gs, a driving gate electrode 109Gd, and a second capacitor electrode 109CA. The first conductive pattern group 109SL, 109Gs, 109Gd, and 109CA may be formed by patterning a first conductive layer using one mask process.

The structures of the scan line 109SL, the switching gate electrode 109Gs, and the driving gate electrode 109Gd, may be the same or substantially the same as described in FIGS. 3A and 3B.

The second capacitor electrode 109CA may overlap the first capacitor electrode 105CA with the first gate insulating layer 107 therebetween. The second capacitor electrode 109CA may be disposed at a lower side (e.g., at a lower surface) of a pixel electrode 121PX. The second capacitor electrode 109CA may be patterned at the same time as the scan line 109SL, the switching gate electrode 109Gs, and the driving gate electrode 109Gd. Thus, no additional mask process for forming the second capacitor electrode 109CA is required.

A portion of the first capacitor electrode 105CA and the protruding portion 105CAp may be exposed by the first conductive pattern group 109SL, 109Gs, 109Gd, and 109CA.

A second gate insulating layer 111 that covers the first conductive pattern group 109SL, 109Gs, 109Gd, and 109CA illustrated in FIG. 4 may be formed on the first gate insulating layer 107.

A protective layer 115 may be formed on the second gate insulating layer 111.

A contact opening group including first to eighth contact openings H1 to H8b may pass through the protective layer 115, the second gate insulating layer 111, and/or the first gate insulating layer 107. The contact opening group may be formed by patterning the protective layer 115, the second gate insulating layer 111, and/or the first gate insulating layer 107 using one mask process.

The first contact opening H1, the second contact opening H2, the third contact opening H3, the fifth contact opening H5, and the seventh contact opening H7b may pass through the protective layer 115, the second gate insulating layer 111, and the first gate insulating layer 107. The first contact opening H1, the second contact opening H2, the third contact opening H3, and the fifth contact opening H5 may be formed the same or substantially the same as described in FIGS. 3A and 3B. The seventh contact opening H7b may expose the protruding portion 105CAp and be disposed at a lower side of the driving voltage line 121VL.

The fourth contact opening H4, the sixth contact opening H6, and the eighth contact opening H8b may pass through the protective layer 115 and the second gate insulating layer 111. The fourth contact opening H4 and the sixth contact opening H6 may be formed the same or substantially the same as described in FIGS. 3A and 3B. The eighth contact opening H8b may expose the second capacitor electrode 109CA by passing through the protective layer 115.

The second conductive pattern group CT1 to CT8b, 121DL, 121Ss, 121Ds, 121L1, 121L2, 121Dd, 121VL, and 121PX may be formed in the contact opening group H1 to H8b and on the protective layer 115. The second conductive pattern group CT1 to CT8b, 121DL, 121Ss, 121Ds, 121L1, 121L2, 121Dd, 121VL, and 121PX may include first to eighth contact portions CT1 to CT8b that fill the contact opening group H1 to H8b, the data line 121DL, the switching source electrode 121Ss, the switching drain electrode 121Ds, the first and second coupling patterns 121L1 and 121L2, the driving drain electrode 121Dd, the driving voltage line 121VL and the pixel electrode 121PX. The second conductive pattern group CT1 to CT8b, 121DL, 121Ss, 121Ds, 121L1, 121L2, 121Dd, 121VL, and 121PX may fill the contact opening group H1 to H8b and be formed on the protective layer 115 by patterning the second conductive layer using one mask process.

The first to seventh contact portions CT1 to CT7b, the data line 121DL, the switching source electrode 121Ss, the switching drain electrode 121Ds, the first and second coupling patterns 121L1 and 121L2, the driving drain electrode 121Dd, the driving voltage line 121VL, and the pixel electrode 121PX may be formed the same or substantially the same as described in FIGS. 3A and 3B. The eighth contact portion CT8b may extend from the first coupling pattern 121 L1, fill an inside of the eighth contact opening H8b, and contact the second capacitor electrode 109CA.

A pixel defining layer 125 that covers the second conductive pattern group CT1 to CT8b, 121DL, 121Ss, 121Ds, 121L1, 121L2, 121Dd, 121VL, and 121PX and includes openings that expose the pixel electrode 121PX may be formed on the protective layer 115. A common electrode 133 may be formed on an organic light emitting layer 131. The pixel electrode 121PX, the organic light emitting layer 131, and the common electrode 133 may form an organic light emitting diode OLED.

According to the above-described structure, the capacitor Cst may include first and second capacitor electrodes 105CA and 109CA facing each other with the first gate insulating layer 109 therebetween, and the capacitor Cst may be disposed at a lower side of the pixel electrode 121PX and may overlap the pixel electrode 121PX. Accordingly, the capacitor Cst may be disposed in the emission region and may not occupy additional space on the substrate 101. Because the first and second capacitor electrodes 105CA and 109CA may be formed as large as the pixel electrode 101PX, the capacity of the capacitor Cst may be sufficiently ensured.

FIG. 6 is a plane view illustrating a pixel according to an embodiment of the present invention.

Referring to FIG. 6, a pixel may be electrically coupled to the scan line 109SL, the data line 121DL, and the driving voltage line 121VL via the switching transistor TRs and the driving transistor TRd. The pixel may include the capacitor Cst coupled to the driving transistor TRd via the first coupling pattern 121L1. The switching transistor TRs and the driving transistor TRd may be electrically coupled to each other via the second coupling pattern 121L2.

The scan line 109SL, the data line 121DL, the first and second coupling patterns 121L1 and 121L2, and the driving voltage line 121VL may be formed to have the same or substantially the same layout as described in FIG. 2.

The switching source electrode 121Ss, the switching drain electrode 121Ds, the switching semiconductor pattern As, and the switching gate electrode 109Gs that make up the switching transistor TRs may be formed to have the same or substantially the same layout as described in FIG. 2. The switching source electrode 121Ss may extend from the data line 121DL and be coupled to the switching semiconductor pattern As via the first contact portion CT1. The switching drain electrode 121Ds may extend from the second coupling pattern 121L2 and be coupled to the switching semiconductor pattern As via the second contact portion CT2.

The driving source electrode (a portion of the driving voltage line 121VL) that makes up the driving transistor TRd, the driving drain electrode 121Dd, the driving semiconductor pattern Ad, and the driving gate electrode 109Gd may be formed to have the same or substantially the same layout as described in FIG. 2. The driving semiconductor pattern Ad may extend to overlap the driving drain electrode 121Dd and be coupled to the driving drain electrode 121Dd via the third contact portion CT3. The driving semiconductor pattern Ad may be coupled to the driving voltage line 121VL via the fifth contact portion CT5 by extending towards the driving voltage line 121VL. The driving gate electrode 109Gd may be coupled to the second coupling pattern 121L1 that is extended to overlap the driving gate electrode 109Gd via the sixth contact portion CT6.

The capacitor Cst may be disposed to overlap the pixel electrode 121PX extending from the driving drain electrode 121Dd to the emission region. The pixel electrode 121PX may be formed to have the same or substantially the same layout as described in FIG. 2. The capacitor Cst may have a relatively large capacity as large as the capacitor Cst described in FIG. 2 because the capacitor Cst overlaps the pixel electrode 121PX.

The capacitor Cst may include the first capacitor electrode 109CA and the second capacitor electrode 113CA overlapping the pixel electrode 121PX.

The first capacitor electrode 109CA may be coupled to the driving transistor TRd via the first coupling pattern 121L1 and the eighth contact portion CT8c. The first coupling pattern 121L1 may extend to overlap the first capacitor electrode 109CA. The eighth contact portion CT8c may be disposed at the overlapping portion of the first coupling pattern 121L1 and the first capacitor electrode 109CA.

The second capacitor electrode 113CA may be coupled to the driving voltage line 121VL via the protruding portion 113CAp and the seventh contact portion CT7c. The protruding portion 113CAp may extend from the second capacitor electrode 113CA and overlap at least a portion of the driving voltage line 121VL. The seventh contact portion CT7c may be disposed at an overlapping portion of the protruding portion 113CAp and the driving voltage line 121VL. The second capacitor electrode 113CA may be formed such that it does not overlap the eighth contact portion CT8c.

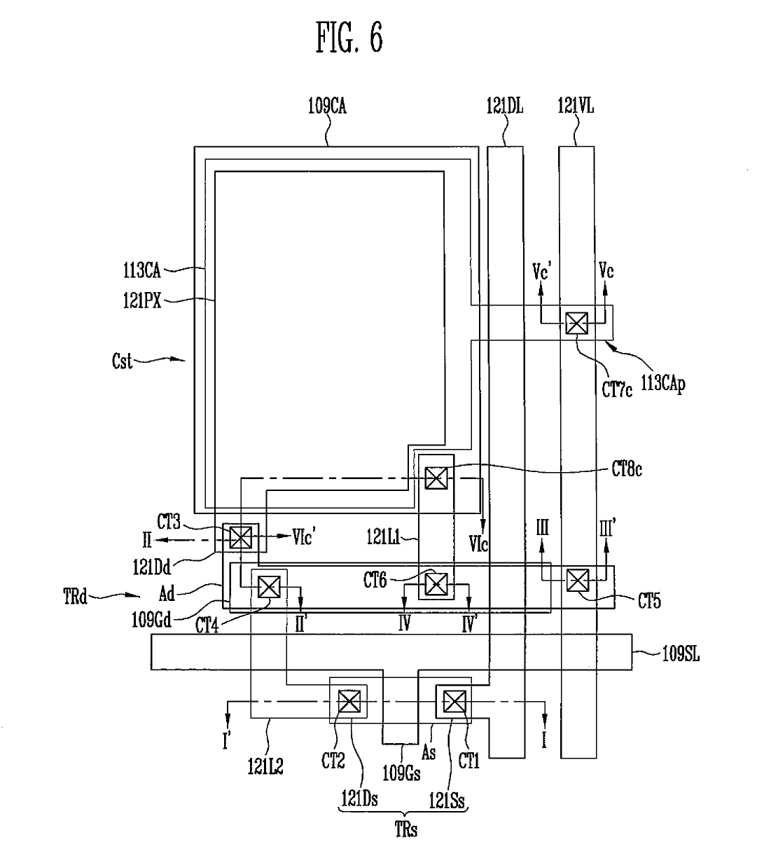

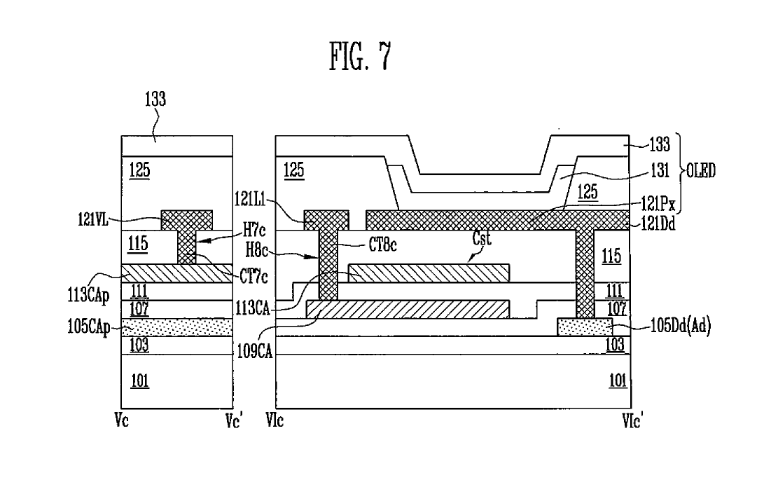

FIG. 7 is a cross-sectional view illustrating the display device shown in FIG.

6 taken along the lines “Vc-Vc′” and “VIc-VIc′”. Cross sections of the display device shown in FIG. 6 taken along the lines “I-I′”, “II-II′”, “III-III′”, and “IV-IV′” shown in FIG. 6 may be the same or substantially the same as those in FIG. 3A.

Referring to FIGS. 3A and 7, the buffer layer 103 may be formed on the substrate 101. The switching transistor TRs, the driving transistor TRd, and the capacitor Cst may be formed on the buffer layer 103.

A semiconductor pattern group As and Ad may be formed on the substrate 101 with the buffer layer 103 therebetween. The semiconductor pattern group As and Ad may include the switching semiconductor pattern As and the driving semiconductor pattern Ad. The semiconductor pattern group As and Ad may be formed by patterning a semiconductor layer using one mask process.

The structure and components of the switching semiconductor pattern As and the driving semiconductor pattern Ad may be the same or substantially the same as described in FIGS. 3A and 3B.

The first gate insulating layer 107 that covers the semiconductor pattern group As and Ad may be formed on the buffer layer 103.

A first conductive pattern group 109SL, 109Gs, 109Gd, and 109CA as shown in FIG. 6 may be formed on the first gate insulating layer 107. The first conductive pattern group 109SL, 109Gs, 109Gd and 109CA may include the scan line 109SL, the switching gate electrode 109Gs, the driving gate electrode 109Gd, and the first capacitor electrode 109CA. The first conductive pattern group 109SL, 109Gs, 109Gd, and 109CA may be formed by patterning the first conductive layer using one mask process.

The structures of the scan line 109SL, the switching gate electrode 109Gs, and the driving gate electrode 109Gd may be the same or substantially the same as in FIGS. 3A and 3B.

The first capacitor electrode 109CA may be disposed at a lower side of the pixel electrode 121 PX. The first capacitor electrode 109CA may be patterned at the same or substantially the same time as (e.g., may be formed concurrently with) the scan line 109SL, the switching gate electrode 109Gs, and the driving gate electrode 109Gd. Thus, no additional mask process for forming the first capacitor electrode 109CA may not be necessary.

The second gate insulating layer 111 that covers the first conductive pattern group 109SL, 109Gs, 109Gd, and 109CA as illustrated in FIG. 6 may be formed on the first gate insulating layer 107.

The second capacitor electrode 113CA and the protruding portion 113CAp may be formed on the second gate insulating layer 111. The second capacitor electrode 113CA may overlap the first capacitor electrode 109CA with the second gate insulating layer 111 therebetween. At least a portion of the first capacitor electrode 109CA may be exposed by the second capacitor electrode 113CA. The second capacitor electrode 113CA may be disposed at a lower side of the pixel electrode 121PX. The protruding portion 113CAp may be a portion that extends from the second capacitor electrode 113CA. The second capacitor electrode 113CA and the protruding portion 113CAp may be formed by patterning a conductive layer using one mask process.

The protective layer 115 that covers the second capacitor electrode 113CA and the protruding portion 113CAp may be formed on the second gate insulating layer 111.

A contact opening group that includes the first to eighth contact openings H1 to H8c may pass through the protective layer 115, the second gate insulating layer 111, and/or the first gate insulating layer 107. The contact opening group may be formed by patterning the protective layer 115, the second gate insulating layer 111, and/or the first gate insulating layer 107 using one mask process.

The first contact opening H1, the second contact opening H2, the third contact opening H3, and the fifth contact opening H5 may pass through the protective layer 115, the second gate insulating layer 111, and the first gate insulating layer 107. The first contact opening H1, the second contact opening H2, the third contact opening H3, and the fifth contact opening H5 may be formed to have the same or substantially the same structures as described in FIGS. 3A and 3B.

The fourth contact opening H4, the sixth contact opening H6, and the eighth contact opening H8c may pass through the protective layer 115 and the second gate insulating layer 111. The fourth contact opening H4 and the sixth contact opening H6 may be formed to have the same or substantially the same structures as described in FIGS. 3A and 3B. The eighth contact opening H8c may expose the first capacitor electrode 109CA by passing through the protective layer 115 and the second gate insulating layer 111. The eighth contact opening H8c may overlap a portion of the first capacitor electrode 109CA exposed by the second capacitor electrode 113CA.

The seventh contact opening H7c may expose the protruding portion 113CAp by passing through the protective layer 115 and be disposed at a lower side of the driving voltage line 121VL.

A second conductive pattern group CT1 to CT8c, 121DL, 121Ss, 121Ds, 121L1, 121L2, 121Dd, 121VL, and 121PX may be formed in the contact opening group H1 to H8c and on the protective layer 115. The second conductive pattern group CT1 to CT8c, 121DL, 121Ss, 121Ds, 121L1, 121L2, 121Dd, 121VL, and 121PX may include the first to eighth contact portions CT1 to CT8c that fill the contact opening group H1 to H8c, the data line 121DL, the switching source electrode 121Ss, the switching drain electrode 121Ds, the first and second coupling patterns 121L1 and 121L2, the driving drain electrode 121Dd, the driving voltage line 121VL, and the pixel electrode 121PX. The second conductive pattern group CT1 to CT8c, 121DL, 121Ss, 121Ds, 121L1, 121L2, 121Dd, 121VL and 121PX may be formed by patterning the second conductive pattern using one mask process, the second conductive pattern filling the contact opening group H1 to H8c and being formed on the protective layer 115.

The first to sixth contact portions CT1 to CT6, the data line 121DL, the switching source electrode 121Ss, the driving drain electrode 121Dd, the driving voltage line 121VL, and the pixel electrode 121PX may be formed to have the same or substantially the same structures as described in FIGS. 3A and 3B. The seventh contact portion CT7c may extend from the driving voltage line 121VL, fill an inside of the seventh contact opening H7c, and contact the protruding portion 113CAp.

The eighth contact portion CT8c may extend from the first coupling pattern 121L1, fill an inside of the eighth contact opening H8c, and contact the first capacitor electrode 109CA.

The pixel defining layer 125 covering the second conductive pattern group CT1 to CT8c, 121D, 121Ss, 121Ds, 121L1, 121L2, 121Dd, 121VL, and 121PX and including openings that expose the pixel electrode 121PX may be formed on the protective layer 115. The organic light emitting layer 131 may be formed on the pixel electrode 121PX that is exposed by the openings in the pixel defining layer 125. The common electrode 133 may be formed on the organic light emitting layer 131. The pixel electrode 121PX, the organic light emitting layer 131, and the common electrode 133 may make up the organic light emitting diode OLED.

According to the above-described structure, the capacitor Cst may include the first and second capacitor electrodes 109CA and 113CA facing each other with the second gate insulating layer 111 therebetween and overlap the lower side of the pixel electrode 121PX. The capacitor Cst may be disposed in the emission region and may not occupy any additional space on the substrate 101. Because the first and second capacitor electrodes 109CA and 113CA may be formed as large as the pixel electrode 121PX, the capacity of the capacitor Cst may be sufficiently ensured.

FIG. 8 is a plane view illustrating a pixel according to an embodiment of the present invention.

Referring to FIG. 8, the pixel may be electrically coupled to the scan line 109SL, the data line 121DL, and the driving voltage line 121VL via the switching transistor TRs and the driving transistor TRd. The pixel may include the capacitor Cst coupled to the driving transistor TRd via the first coupling pattern 121L1. The switching transistor TRs and the driving transistor TRd may be electrically coupled to each other via the second coupling pattern 121L2.

The scan line 109SL, the data line 121DL, the first and second coupling patterns 121L1 and 121L2, and the driving voltage line 121VL may be formed to have the same or substantially the same layout as described in FIG. 2.

The switching source electrode 121Ss, the switching drain electrode 121Ds, the switching semiconductor pattern As, and the switching gate electrode 109Gs that make up the switching transistor TRs may be formed to have the same or substantially the same layout as described in FIG. 2. The switching source electrode 121Ss may extend from the data line 121DL and be coupled to the switching semiconductor pattern As via the first contact portion CT1. The switching drain electrode 121Ds may extend from the second coupling pattern 121L2 and be coupled to the switching semiconductor pattern As via the second contact portion CT2.

The driving source electrode (a portion of the driving voltage line 121VL), the driving drain electrode 121Dd, the driving semiconductor pattern Ad, and the driving gate electrode 109Gd that make up the driving transistor TRd may be formed to have the same or substantially the same layout as described in FIG. 2. The driving semiconductor pattern Ad may be coupled to the driving drain electrode 121Dd via the third contact portion CT3b by extending to overlap the driving drain electrode 121Dd. The driving semiconductor pattern Ad may be coupled to the driving voltage line 121VI via the fifth contact portion CT5 by extending towards the driving voltage line 121VL. The driving gate electrode 109Gd may be coupled to the second coupling pattern 121L1 by extending to overlap the driving gate electrode 109Gd via the sixth contact portion CT6.

The capacitor Cst may be disposed to overlap the pixel electrode 121PX extending from the driving drain electrode 121Dd to the emission region. The pixel electrode 121PX may be formed to have the same or substantially the same layout as described in FIG. 2. The pixel electrode 121PX may be formed to be spaced from the third coupling pattern 121L3 that is further described below. Because the capacitor Cst may overlap the pixel electrode 121PX, the capacitor Cst may have a capacity as large as is described in FIG. 2.

The capacitor Cst may include a first capacitor lower electrode 105CA, the second capacitor electrode 109CA, and a first capacitor upper electrode 113CA overlapping the pixel electrode 121PX. At least one edge of the first capacitor lower electrode 105CA may protrude more than (e.g., may protrude beyond) the second capacitor electrode 109CA and the first capacitor upper electrode 113CA. The second capacitor electrode 109CA may overlap the first capacitor lower electrode 105CA and be formed to expose the at least one edge of the first capacitor lower electrode 105CA. The first capacitor upper electrode 113CA may overlap the second capacitor electrode 109CA and be formed to expose at least a portion of the second capacitor electrode 109CA that is adjacent to the driving gate electrode 109Gd.

The second capacitor electrode 109CA may be coupled to the driving transistor TRd via the first coupling pattern 121L1 and the eighth contact portion CT8d. The first coupling pattern 121L1 may extend to overlap the second capacitor electrode 109CA and the driving gate electrode 109Gd. The first coupling pattern 121L1 may extend to overlap a portion of the second capacitor electrode 109CA exposed by the first capacitor upper electrode 113CA. The eighth contact portion CT8d may be disposed at an overlapping portion of a portion of the second capacitor electrode 109CA that is exposed by the first capacitor upper electrode 113CA and the first coupling pattern 121L1.

The first capacitor lower electrode 105CA and the first capacitor upper electrode 113CA may be electrically coupled to each other via the third coupling pattern 121L3, the ninth contact portion CT9, and the tenth contact portion CT10. The third coupling pattern 121L3 may extend to overlap the first capacitor lower electrode 105CA and the first capacitor upper electrode 113CA. The third coupling pattern 121L3 may extend to overlap a portion of the first capacitor upper electrode 113CA and a portion of the first capacitor lower electrode 105CA exposed by the second capacitor electrode 109CA. The ninth contact portion CT9 may be disposed at an overlapping portion of a portion of the first capacitor lower electrode 105CA exposed by the first capacitor upper electrode 113CA and the second capacitor electrode 109CA and the third coupling pattern 121L3. The tenth contact portion CT10 may be disposed at an overlapping portion of the first capacitor upper electrode 113CA and the third coupling pattern 121L3.

The first capacitor upper electrode 113CA may be coupled to the driving voltage line 121VL via the protruding portion 113CAp and the seventh contact portion CT7d. The protruding portion 113CAp may overlap at last a portion of the driving voltage line 121VL by extending from the first capacitor upper electrode 113CA. The seventh contact portion CT7d may be disposed at an overlapping portion of the protruding portion 113CAp and the driving voltage line 121VL.

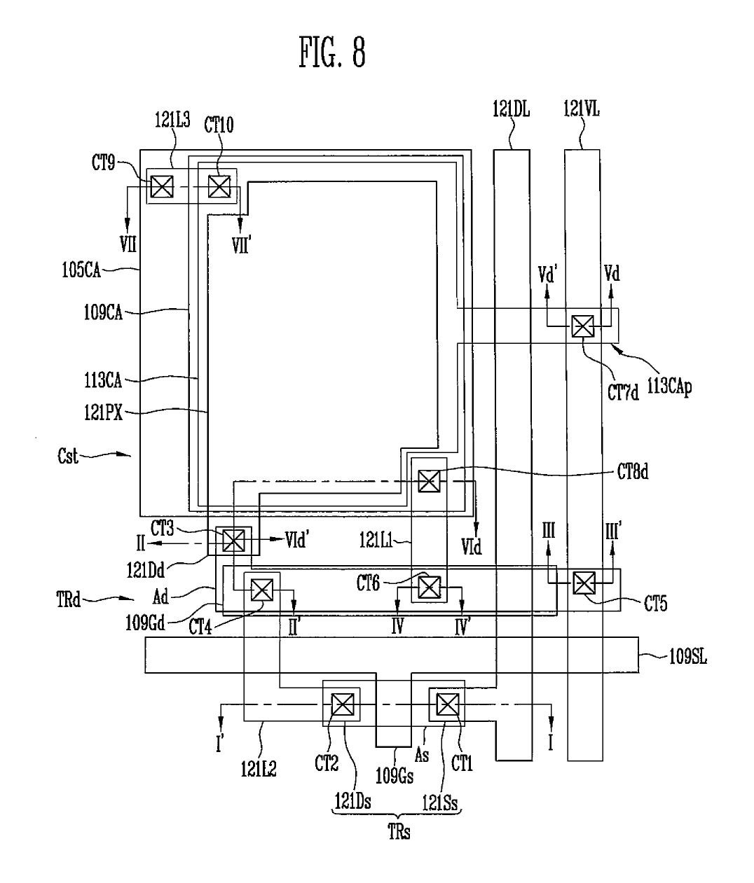

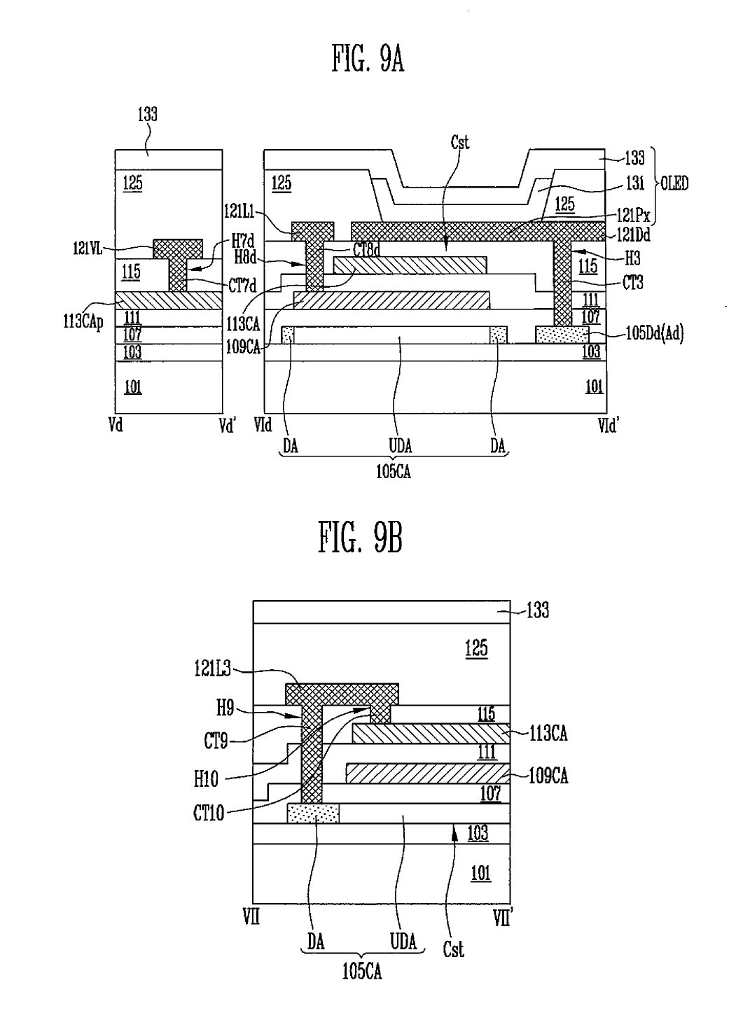

FIGS. 9A and 9B are cross-sectional views illustrating the display device shown in FIG. 8 taken along the lines “Vd-Vd′”, “VId-VId′”, and “VII-VII′” in FIG. 8. Cross sections of the display device shown in FIG. 8 taken along the lines “I-I′”, “II-II′”, “III-III′”, and “IV-IV′” in FIG. 8 may be the same or substantially the same as those shown in FIG. 3A.

Referring to FIGS. 3A, 9A, and 9B, a buffer layer 103 may be formed on a substrate 101. A switching transistor TRs, a driving transistor TRd, and a capacitor Cst may be formed on the buffer layer 103.

A semiconductor pattern group As, Ad, and 105CA may be formed on the substrate 101 with the buffer layer 103 therebetween. The semiconductor pattern group As, Ad, and 105CA may include a switching semiconductor pattern As, a driving semiconductor pattern Ad, and a first capacitor lower electrode 105CA. The semiconductor pattern group As, Ad, and 105CA may be formed by patterning a semiconductor layer using one mask process.

The structure and components of the switching semiconductor pattern As and the driving semiconductor pattern Ad may be the same or substantially the same as described in FIGS. 3A and 3B. The first capacitor lower electrode 105CA may be disposed at a lower side of the first pixel electrode 121PX. The first capacitor lower electrode 105CA may include an overlapped region and a non-overlapped region at a second capacitor electrode 109CA. The first capacitor lower electrode 105CA may include an un-doped area UDA and a doped area DA. The un-doped area UDA may be a region that overlaps the second capacitor electrode 109CA, and the doped area

DA may be a region that does not overlap the second capacitor electrode 109CA. The doped area DA of the first capacitor electrode 105CA may include impurities of a same type as source regions 105Ss and 105Sd and drain regions 105Ds and 105Dd.

A first gate insulating layer 107 that covers the semiconductor pattern group As, Ad, and 105CA may be formed on the buffer layer 103.

A first conductive pattern group 109SL, 109Gs, 109Gd, and 109CA in FIG. 8 may be formed on the first gate insulating layer 107. The first conductive pattern group 109SL, 109Gs, 109Gd, and 109CA may include a scan line 109SL, a switching gate electrode 109Gs, a driving gate electrode 109Gd, and a second capacitor electrode 109CA. The first conductive pattern group 109SL, 109Gs, 109Gd, and 109CA may be formed by patterning a first conductive layer using one mask process.

The structures of the scan line 109SL, the switching gate electrode 109Gs, and the driving gate electrode 109Gd may be the same or substantially the same as described in FIGS. 3A and 3B.

The second capacitor electrode 109CA may be disposed between the first capacitor lower electrode 105CA and a first pixel electrode 121PX. Because the second capacitor electrode 109CA is patterned at the same or substantially the same time as (e.g., concurrently with) the scan line 109SL, the switching gate electrode 109Gs, and the driving gate electrode 109Gd, no additional mask process for forming the second capacitor electrode 109CA may be necessary. A portion of the first capacitor electrode 105CA may be exposed by the first conductive pattern group 109SL, 109Gs, 109Gd, and 109CA.

A second gate insulating layer 111 that covers the first conductive pattern group 109SL, 109Gs, 109Gd, and 109CA illustrated in FIG. 8 may be formed on the first gate insulating layer 107.

A first capacitor upper electrode 113CA and a protruding portion 113CAp may be formed on the second gate insulating layer 111. The first capacitor upper electrode 113CA may overlap the second capacitor electrode 109CA with the second gate insulating layer 111 therebetween. At least a portion of the second capacitor electrode 109CA adjacent to the driving gate electrode 109Gd may be exposed by the first capacitor upper electrode 113CA. The first capacitor upper electrode 113CA may be disposed between the pixel electrode 121 PX and the second capacitor electrode 109CA. The protruding portion 113CAp may be a portion that extends from the first capacitor upper electrode 113CA. The first capacitor upper electrode 113CA and the protruding portion 113CAp may be formed by patterning a capacitor conductive layer using one mask process.

A protective layer 115 that covers the first capacitor upper electrode 113CA and the protruding portion 113CAp may be formed on the second gate insulating layer 111.

A contact opening group that includes first to tenth contact openings H1 to H10 may pass through the protective layer 115, the second gate insulating layer 111, and/or the first gate insulating layer 107. The contact opening group may be formed by patterning the protective layer 115, the second gate insulating layer 111, and/or the first gate insulating layer 107 using one mask process.

The first contact opening H1, the second contact opening H2, the third contact opening H3, the fifth contact opening H5, and the ninth contact opening H9 may pass through the protective layer 115, the second gate insulating layer 111, and the first gate insulating layer 107. The first contact opening H1, the second contact opening H2, the third contact opening H3, and the fifth contact opening H5 may be formed to have the same or substantially the same structures as described in FIGS. 3A and 3B. The ninth contact opening H9 may expose the first capacitor lower electrode 105CA. The ninth contact opening H9 may expose a doped area DA of the first capacitor lower electrode 105CA that is exposed by the second capacitor electrode 109CA and the first capacitor upper electrode 113CA. The ninth contact opening H9 may be disposed at the lower side of the third coupling pattern 121L3.

The fourth contact opening H4, the sixth contact opening H6, and the eighth contact opening H8d may pass through the protective layer 115 and the second gate insulating layer 111. The fourth contact opening H4 and the sixth contact opening H6 may be formed to have the same or substantially the same structures as described in FIGS. 3A and 3B. The eighth contact opening H8d may expose the second capacitor electrode 109CA by passing through the protective layer 115 and the second gate insulating layer 111. The eighth contact opening H8d may overlap a portion of the second capacitor electrode 109CA exposed by the first capacitor upper electrode 113CA.

The seventh contact opening H7d and the tenth contact opening H10 may pass through the protective layer 115. The seventh contact opening H7d may expose the protruding portion 113CAp and be disposed at the lower side of the driving voltage line 121VL. The tenth contact opening H10 may expose the first capacitor upper electrode 113CA and be disposed at the lower side of the third coupling pattern 121L3.

A second conductive pattern group CT1 to CT10, 121DL, 121Ss, 121Ds, 121L1, 121L2, 121L3, 121Dd, 121VL, and 121PX may be formed in the contact opening group H1 to H10 and on the protective layer 115. The second conductive pattern group CT1 to CT10, 121DL, 121Ss, 121Ds, 121L1, 121L2, 121L3, 121Dd, 121VL, and 121PX may include first to tenth contact portions CT1 to CT10 that fill the contact opening group H1 to H10, a data line 121DL, a switching source electrode 121Ss, a switching drain electrode 121Ds, first to third coupling patterns 121L1 to 121L3, a driving drain electrode 121Dd, a driving voltage line 121VL, and a pixel electrode 121PX. The second conductive pattern group CT1 to CT10, 121DL, 121Ss, 121Ds, 121L1, 121L2, 121L3, 121Dd, 121VL, and 121PX may be formed by patterning a second conductive layer filling the contact opening group H1 to H10 and formed on the protective layer 115 using one mask process.

The first to sixth contact portions CT1 to CT6, the data line 121DL, the switching source electrode 121Ss, the switching drain electrode 121Ds, the first and second coupling patterns 121L1 and 121L2, the driving drain electrode 121Dd, and the driving voltage line 121VL may be formed to have the same or substantially the same structures as described in FIGS. 3A and 3B.

The pixel electrode 121PX may be disposed on the protective layer 115 and extend from the driving drain electrode 121Dd to the emission region. A first capacitor lower electrode 105CA, a second capacitor electrode 109CA, and a first capacitor upper electrode 113CA may overlap the pixel electrode 121PX at a lower side of the pixel electrode 121PX. The pixel electrode 121PX may be formed to expose the first capacitor lower electrode 105CA and the first capacitor upper electrode 113CA. The pixel electrode 121PX may be formed to expose a portion of the second capacitor electrode 109CA that does not overlap the first capacitor upper electrode 113CA.

The seventh contact portion CT7d may fill an inside of the seventh contact opening H7d by extending from the driving voltage line 121VL and contact the protruding portion 113CAp.

The eighth contact portion CT8d may fill an inside of the eighth contact opening H8c by extending from the first coupling pattern 121L1 and contact the second capacitor electrode 109CA.

The ninth contact portion CT9 may fill an inside of the ninth contact opening H9 by extending from the third coupling pattern 121L3 and may contact the first capacitor lower electrode 105CA. The ninth contact portion CT9 may contact the doped area DA of the first capacitor lower electrode 105CA exposed by the second capacitor electrode 109CA and the first capacitor upper electrode 113CA.

The tenth contact portion CT10 may fill an inside of the tenth contact opening H10 by extending from the third coupling pattern 121L3 and may contact the first capacitor upper electrode 113CA.

A pixel defining layer 125 that covers the second conductive pattern group CT1 to CT10, 121DL, 121Ss, 121Ds, 121L1, 121L2, 121L3, 121Dd, 121VL, and 121PX and that has openings which expose the pixel electrode 121PX may be formed on the protective layer 115. An organic light emitting layer 131 may be formed on the pixel electrode 121PX that is exposed by the openings in the pixel defining layer 125. A common electrode 133 may be formed on the organic light emitting layer 131. The pixel electrode 121PX, the organic light emitting layer 131, and the common electrode 133 may make up an organic light emitting diode OLED.

According to the above described structure, a capacitor Cst may include first and second capacitors that are coupled in parallel. The first capacitor may include the first capacitor lower electrode 105CA and the second capacitor electrode 109CA facing each other with the first gate insulating layer 107 therebetween. The second capacitor may include the first capacitor upper electrode 113CA and the second capacitor electrode 109CA facing each other with the second gate insulating layer 111 therebetween. The capacitor Cst may have a relatively large capacity by including the first and second capacitors that are coupled in parallel. The first and second capacitors may overlap the pixel electrode 121PX at a lower side of the pixel electrode 121PX. The capacitor Cst may be disposed in the emission region and may not occupy additional space on the substrate 101. Because each of the first capacitor lower electrode 105CA, the second capacitor electrode 109CA, and the first capacitor upper electrode 113CA may be formed as large as the pixel electrode 121PX, the capacity of the capacitor Cst may be sufficiently ensured.

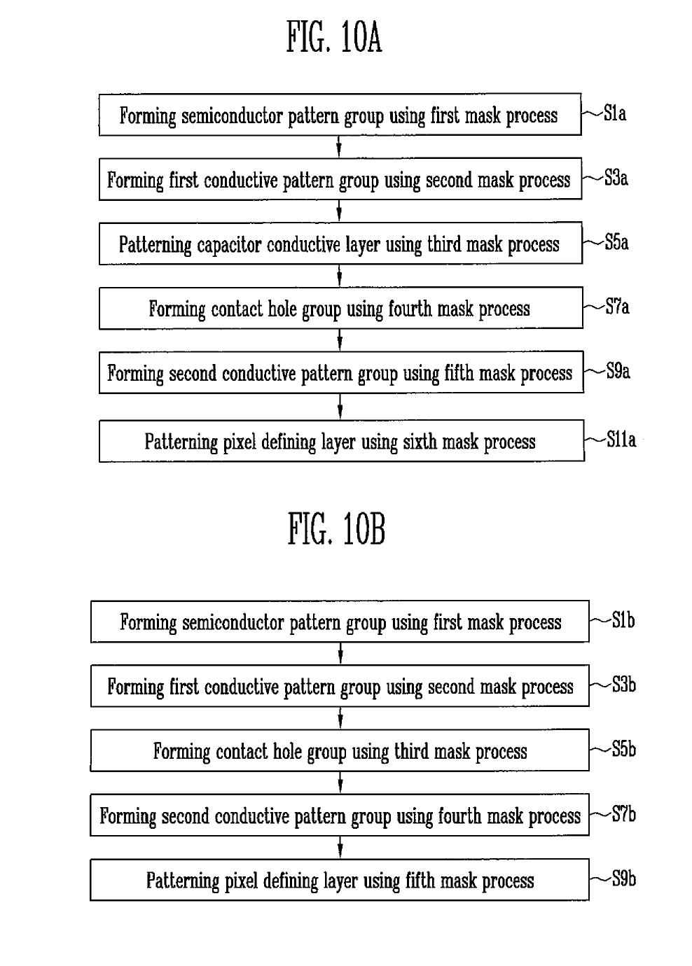

FIGS. 10A and 10B illustrate a mask process for manufacturing a display device according to an embodiment of the present invention. FIG. 10A illustrates a manufacturing method of a display device according to embodiments of the present invention shown in FIGS. 2, 3A, 3B, 6, 7, 8, 9A, and 9B. FIG. 10B illustrates a manufacturing method of a display device according to embodiments of the present invention shown in FIGS. 4 and 5.

Referring to FIG. 10A, after the semiconductor layer is formed on the substrate on which the buffer layer is formed, the semiconductor layer is patterned using a first mask process. The semiconductor pattern group that is described in FIGS. 2, 3A, 3B, 6, 7, 8, 9A, and 9B may be formed (S1a). After S1a, the first mask may be removed.

The first gate insulating layer that covers the semiconductor pattern group may be formed on the buffer layer, and the first conductive layer may be formed on the first gate insulating layer. The first conductive pattern group as described in FIGS. 2, 3A, 3B, 6, 7, 8, 9A, and 9B may be formed by patterning the first conductive layer using a second mask process (S3a). Source regions, drain regions, and doping regions may be formed by injecting impurities into at least a portion of the semiconductor pattern group exposed by the first conductive pattern group. When the impurities are injected, a second mask or the first conductive pattern group may be used as an impurity injection barrier. After S3a, the second mask may be removed.

The second gate insulating layer that covers the first conductive pattern group may be formed on the first gate insulating layer, and the capacitor conductive layer may be formed on the second gate insulating layer. The capacitor conductive layer may be patterned using a third mask process to form the capacitor electrode described in FIGS. 2, 3A, 3B, 6, 7, 8, 9A, and 9B (S5a). In S5a, the protruding portion protruding from the capacitor electrode may be patterned at the same or substantially the same time as (e.g., concurrently with) the capacitor electrode. After S5a, a third mask may be removed.

The protective layer that covers the capacitor electrode may be formed on the second gate insulating layer. The contact opening group described in FIGS. 2, 3A, 3B, 6, 7, 8, 9A, and 9B may be formed using a fourth mask process (S7a). After S7a, a fourth mask may be removed.

The second conductive layer may be formed on the protective layer to fill the contact opening group (e.g., to fill the various openings of the contact opening group). By patterning the second conductive layer using a fifth mask process, the second conductive pattern group described in FIGS. 2, 3A, 3B, 6, 7, 8, 9A, and 9B may be formed (S9a). After S9a, a fifth mask may be removed.

A pixel defining layer may be formed on the protective layer to cover the second conductive layer. The pixel defining layer may be patterned using a sixth mask process, and the openings that expose the pixel electrode described in FIGS. 2, 3A, 3B, 6, 7, 8, 9A, and 9B may be formed (S11a).

The organic light emitting layer and the buffer layer may be formed.

Referring to FIG. 10B, after the semiconductor layer is formed on the buffer layer, the semiconductor pattern group described in FIGS. 4 and 5 may be formed by patterning the semiconductor layer using the first mask process (S1b). After S1b, the first mask may be removed.

The first gate insulating layer that covers the semiconductor pattern group may be formed on the buffer layer, and the first conductive layer may be formed on the first gate insulating layer. The first conductive layer may be patterned using the second mask process, and the first conductive pattern group described in FIGS. 4 and 5 may be formed (S3b). Using the second mask or the first conductive pattern group as an impurity injection barrier, impurities may be injected into at least a portion of the semiconductor pattern group exposed by the first conductive pattern group, thereby forming source regions, drain regions, and doping regions. After S3b, the second mask may be removed.

The second gate insulating layer that covers the first conductive pattern group may be formed on the first gate insulating layer, and the protective layer may be formed on the second gate insulating layer. The contact opening group described in FIGS. 4 and 5 may be formed using the third mask process (S5b). After S5b, the third mask may be removed.

The second conductive layer may be formed on the protective layer to fill the contact opening group. By patterning the second conductive layer using the fourth mask process, the second conductive pattern group described in FIGS. 4 and 5 may be formed (S7b). After S7b, the fourth mask may be removed.

The pixel defining layer may be formed on the protective layer to cover the second conductive layer. By patterning the pixel defining layer using the fifth mask process, the openings that expose the pixel electrode described in FIGS. 4 and 5 may be formed (S9b).

The organic light emitting layer and the buffer layer may be formed.

By way of summation and review, according to embodiments of the present invention, a capacitor may be disposed to overlap a pixel electrode in a relatively large emission area. Thus, charging capacity of capacitor may be sufficiently ensured as a result.

In embodiments of the present invention, the capacitor overlapping the pixel electrode may be electrically coupled to a gate electrode of a driving transistor via a coupling pattern.

In embodiments of the present invention, by forming a coupling pattern at the same or substantially the same time as (e.g., concurrently with) the pixel electrode, a source electrode, and a drain electrode, no additional mask processes are necessary in order to couple the capacitor that overlaps the pixel electrode to the driving transistor.

Example embodiments of the present invention have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims and their equivalents.

What is claimed is:

1. A display device, comprising:
a first conductive pattern group comprising a scan line and a gate electrode spaced from the scan line;
a driving semiconductor pattern below the first conductive pattern group and comprising:
a channel region overlapping the gate electrode;
a source region; and
a drain region, the channel region between the source region and the drain region;
a second conductive pattern group on the first conductive pattern group and comprising:
a data line crossing the scan line;
a drain electrode coupled to the drain region;
a pixel electrode extending from the drain electrode;
a first coupling pattern coupled to the gate electrode; and
a driving voltage line coupled to the source region; and
a capacitor coupled to the first coupling pattern and the driving voltage line and overlapping the pixel electrode.

2. The display device as claimed in claim 1, wherein the capacitor comprises:
a first capacitor electrode spaced from the driving semiconductor pattern below the first conductive pattern group and overlapping the pixel electrode;
a first gate insulating layer on the driving semiconductor pattern and the first capacitor electrode below the first conductive pattern group;
a second gate insulating layer on the first gate insulating layer and the first conductive pattern group below the second conductive pattern group; and
a second capacitor electrode on the first capacitor electrode with the first and second gate insulating layers therebetween.

3. The display device as claimed in claim 2, further comprising:
a protruding portion extending from the first capacitor electrode and overlapping the driving voltage line;
a protective layer on the second capacitor electrode and below the second conductive pattern group; and
a contact portion extending from the driving voltage line towards the protruding portion and passing through the protective layer and the first and second gate insulating layers, the contact portion contacting the protruding portion.

4. The display device as claimed in claim 2, further comprising:
a protective layer on the second capacitor electrode and below the second conductive pattern group; and
a contact portion extending from the first coupling pattern towards the second capacitor electrode and passing through the protective layer, the contact portion contacting the second capacitor electrode.

5. The display device as claimed in claim 2, wherein the first capacitor electrode comprises a semiconductor pattern.

6. The display device as claimed in claim 2, wherein the first capacitor electrode comprises impurities of a same type as that of the source region and the drain region.

7. The display device as claimed in claim 2, wherein the second capacitor electrode comprises a metal layer.

8. The display device as claimed in claim 1, wherein the capacitor comprises:
a first capacitor electrode spaced from the driving semiconductor pattern below the first conductive pattern group and overlapping the pixel electrode;
a first gate insulating layer on the driving semiconductor pattern and the first capacitor electrode below the first conductive pattern group; and
a second capacitor electrode on the first capacitor electrode with the first gate insulating layer therebetween and spaced from the scan line and the gate electrode,
wherein the first conductive pattern group further comprises the second capacitor electrode.

9. The display device as claimed in claim 8, further comprising:
a protruding portion extending from the first capacitor electrode and overlapping the driving voltage line;
a second gate insulating layer on the first conductive pattern group and below the second conductive pattern group;
a protective layer on the second gate insulating layer below the second conductive pattern group; and
a contact portion extending from the driving voltage line towards the protruding portion and passing through the protective layer and the first and second gate insulating layers, the contact portion contacting the protruding portion.

10. The display device as claimed in claim 8, further comprising:
a second gate insulating layer on the first conductive pattern group and below the second conductive pattern group;
a protective layer on the second gate insulating layer below the second conductive pattern group; and
a contact portion extending from the first coupling pattern towards the second capacitor electrode and passing through the protective layer and the second gate insulating layer, the contact portion contacting the second capacitor electrode.

11. The display device as claimed in claim 8, wherein the first capacitor electrode comprises a semiconductor pattern.

12. The display device as claimed in claim 8, wherein the first capacitor electrode comprises an undoped area overlapping the second capacitor electrode and a doped area offset from the second capacitor electrode.

13. The display device as claimed in claim 12, wherein the doped area comprises impurities of a same type as that of the source region and the drain region.

14. The display device as claimed in claim 1, wherein the capacitor comprises:
a first capacitor electrode overlapping the pixel electrode on a first gate insulating layer, on the driving semiconductor pattern, and spaced from the scan line and the gate electrode;
a second gate insulating layer on the first conductive pattern group and on the first gate insulating layer; and
a second capacitor electrode on the first capacitor electrode with the second gate insulating layer therebetween and below the second conductive pattern group,
wherein the first conductive pattern group further comprises the first capacitor electrode.

15. The display device as claimed in claim 14, further comprising:
a protective layer on the second capacitor electrode below the second conductive pattern group and on the second gate insulating layer; and
a contact portion extending from the first coupling pattern towards the first capacitor electrode and passing through the protective layer and the second gate insulating layer, the contact portion contacting the first capacitor electrode.

16. The display device as claimed in claim 14, further comprising:
a protruding portion extending from the second capacitor electrode and overlapping the driving voltage line;
a protective layer on the second capacitor electrode, on the protruding portion and below the second conductive pattern group; and
a contact portion extending from the driving voltage line towards the protruding portion and passing through the protective layer, the contact portion contacting the protruding portion.

17. The display device as claimed in claim 14, wherein the second capacitor electrode comprises a metal layer.

18. The display device as claimed in claim 1, wherein the capacitor comprises:
a first capacitor lower electrode overlapping the pixel electrode and spaced from the driving semiconductor pattern;
a first gate insulating layer on the driving semiconductor pattern and the first capacitor lower electrode;
a second capacitor electrode overlapping the first capacitor lower electrode on the first gate insulating layer and spaced from the scan line and the gate electrode;
a second gate insulating layer on the first conductive pattern group and on the first gate insulating layer; and
a first capacitor upper electrode coupled to the first capacitor lower electrode and overlapping the second capacitor electrode,
wherein the first conductive pattern group further comprises the second capacitor electrode.

19. The display device as claimed in claim 18, wherein the first capacitor lower electrode comprises:
an undoped area overlapping the second capacitor electrode; and
a doped area offset from the second capacitor electrode and comprising impurities of a same type as that of the source region and the drain region.

20. The display device as claimed in claim 18, further comprising:
a protective layer on the first capacitor upper electrode below the second conductive pattern group and on the second gate insulating layer;
a protruding portion extending from the first capacitor upper electrode to overlap the driving voltage line;
a first contact portion extending from the driving voltage line towards the protruding portion and passing through the protective layer, the first contact portion contacting the protruding portion;
a second contact portion extending from the first coupling pattern towards the second capacitor electrode and passing through the protective layer and the second gate insulating layer, the second contact portion contacting the second capacitor electrode;
a second coupling pattern on the protective layer and overlapping the first capacitor lower electrode and the first capacitor upper electrode;
a third contact portion extending from the second coupling pattern towards the first capacitor lower electrode and passing through the protective layer and the first and second gate insulating layers, the third contact portion contacting the first capacitor lower electrode; and
a fourth contact portion extending from the second coupling pattern towards the first capacitor upper electrode and passing through the protective layer, the fourth contact portion contacting the first capacitor upper electrode,
wherein the second conductive pattern group further comprises the second coupling pattern.
